(19) United States
(12) Patent Application Publication
(10) Pub. No.: US 2024/0365544 A1
(43) Pub. Date: Oct. 31, 2024

(54) THREE-DIMENSIONAL MEMORIES, MANUFACTURING METHODS THEREOF, AND MEMORY SYSTEMS

(71) Applicant: Yangtze Memory Technologies Co., Ltd., Wuhan (CN)

(72) Inventors: Quanshan Lv, Wuhan (CN); Jie Yuan, Wuhan (CN); YaLi Song, Wuhan (CN)

(21) Appl. No.: 18/473,896

(22) Filed: Sep. 25, 2023

Related U.S. Application Data
(63) Continuation of application No. PCT/CN2023/091282, filed on Apr. 27, 2023.

(51) Int. Cl. H10B 43/27; H10B 41/27; H10B 41/35; H10B 41/40; H10B 43/35; H10B 43/40

(52) U.S. Cl. CPC H10B 43/27; H10B 41/27; H10B 41/35; H10B 41/40; H10B 43/35; H10B 43/40

(57) ABSTRACT

Examples of the present application provide a three-dimensional memory and manufacturing method thereof, and a memory system. The three-dimensional memory comprises: a stack structure comprising alternating stacked gate layers and dielectric layers; a plurality of channel columns penetrating the stack structure in a first direction and comprising: a barrier layer, a storage layer, a tunneling layer, and a channel layer arranged in sequence; and a plurality of isolation structures located between the dielectric layers and the tunneling layer in a second direction perpendicular to the first direction; wherein the isolation structures penetrating at least a portion of the storage layer in the second direction.

### REFERENCE TO RELATED APPLICATION

This application is a continuation of International Patent Application PCT/CN2023/091282, filed on Apr. 27, 2023, which is hereby incorporated by reference in its entirety.

### TECHNICAL FIELD

The present application relates to the field of semiconductor technologies, and relates to, but is not limited to, three-dimensional memories, manufacturing methods thereof, and memory systems.

### BACKGROUND

A three-dimensional memory includes stacked gate layers insulated from each other, and a channel column that penetrates the gate layers. The channel column includes a barrier layer, a storage layer (a charge trap layer), a tunneling layer and a channel layer in a radial direction of the channel column. When the memory is being programmed, the electrons in the channel layer are injected into the storage layer through the tunneling layer under the voltage of the gate layers, and the traps in the storage layer capture electrons for information storage.

To increase the storage density of the three-dimensional memory, the number of stacked gate layers can be increased, and the radial size of the channel column can also be reduced, thereby increasing the number of memory cells per wafer area, and thus increasing the storage density.

### BRIEF DESCRIPTION OF THE DRAWINGS

FIGS. 1A-1G are schematic diagrams illustrating a manufacturing method of a three-dimensional memory according to an example of the present disclosure;

FIG. 2 is a first schematic structural diagram illustrating a three-dimensional memory according to an example of the present disclosure;

FIG. 3 is a second schematic structural diagram illustrating a three-dimensional memory according to an example of the present disclosure;

FIG. 4 is a third schematic structural diagram illustrating a three-dimensional memory according to an example of the present disclosure;

FIG. 5 is a schematic flowchart illustrating a manufacturing method of a three-dimensional memory according to an example of the present disclosure;

FIGS. 6A-6K are schematic diagrams illustrating a manufacturing method of a three-dimensional memory according to an example of the present disclosure;

FIG. 7 is a schematic diagram illustrating an example system with a memory system according to an example of the present disclosure;

FIG. 8A is a schematic diagram illustrating an example memory card with a memory system according to an example of the present disclosure;

FIG. 8B is a schematic diagram illustrating an example solid-state drive with a memory system according to an example of the present disclosure;

FIG. 9 is a schematic diagram illustrating an example memory device including peripheral circuits according to an example of the present disclosure; and

FIG. 10 is a schematic diagram illustrating an example memory device including a memory array and peripheral circuits according to an example of the present disclosure.

### DETAILED DESCRIPTION

The technical solutions of the present disclosure will be further described in detail below in conjunction with the accompanying drawings and specific examples.

In the examples of the present disclosure, the terms “first,” “second,” etc. in the present disclosure are used to identify similar objects, rather than describe a particular order or sequence.

In the examples of the present disclosure, the term “A is in contact with B” includes a situation where A is in direct contact with B, or a situation where A is indirectly in contact with B with other components interposed between A and B.

In the examples of the present disclosure, the term “layer” refers to a material portion including a region with a thickness. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between, or between any set of horizontal planes at, a top surface and a bottom surface of the continuous structure. A layer can extend horizontally, vertically, and/or along a tapered surface. Also, a layer may include a plurality of sublayers.

It should be readily understood that the meaning of “on,” “above,” and “over” in the present disclosure should be interpreted in the broadest manner such that “on” not only means “on” something with no intermediate feature or layer there between (i.e., directly on something), but also includes the meaning of “on” something with an intermediate feature or a layer there between.

It is noted that, although this description is described according to examples, not each example includes only an independent technical solution. This recitation manner in the description is only for the sake of clarity, and those skilled in the art should take the description as a whole. The technical solutions in the various examples can also be properly combined to form other examples that can be understood by those skilled in the art.

Regardless of the increase in the number of stacked gate layers and the reduction in the size of the channel column, the film layer morphology of the channel column is difficult to control, which reduces the performance of the device and the stability of the three-dimensional memory.

Improvement of the stability of the three-dimensional memory has become an urgent problem to be solved.

In a three-dimensional NAND memory, a stack structure comprising alternating stacked gate layers and dielectric layers is included, and a channel column penetrates the stack structure. The storage layer in the channel column is a continuous film structure, the gate layers control a section of the storage layer corresponding thereto, and a portion of the storage layer corresponding to the dielectric layers is not controlled by the gate layers. That is, electrons only need to be stored in a section of the storage layer corresponding to the gate layers. It can be understood that the storage layer is a continuous film structure, and the electrons in the storage layers corresponding to the adjacent gate layers will migrate to each other and cause leakage, which will cause the threshold voltage to shift, resulting in the failure of the verification operation in the programming (writing) phase or incapability of correct reading. However, when the number of stacked layers increases, the size of the channel column decreases, the uniformity of morphology of the channel column is poor, and the uniformity of the film thickness of the storage layer is also poor. Bounding or trapping capability of the storage layer for electrons is weakened, and therefore, the leakage risk between the storage layers corresponding to the gate layers is aggravated, thus reducing the stability of the three-dimensional memory. In this regard, an example of the present disclosure proposes a manufacturing method of a three-dimensional memory. The manufacturing method forms a discontinuous storage layer, wherein the storage layer comprising a plurality of electrically isolated storage sublayers, and each storage sublayer corresponding to a gate layer to reduce the mutual leakage between the storage sublayers, thus improve the stability of the three-dimensional memory. The manufacturing method includes:

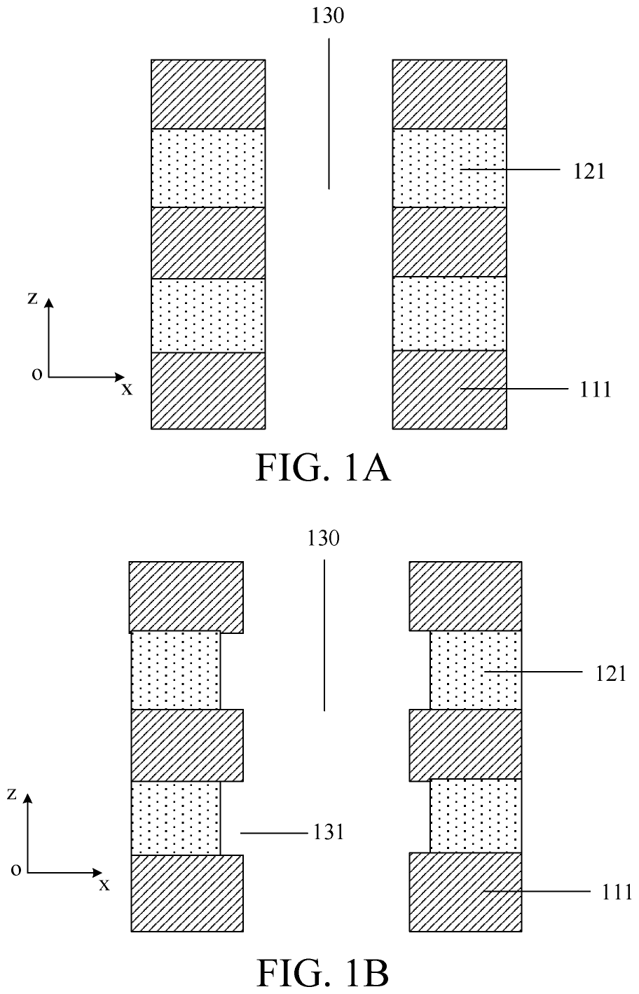

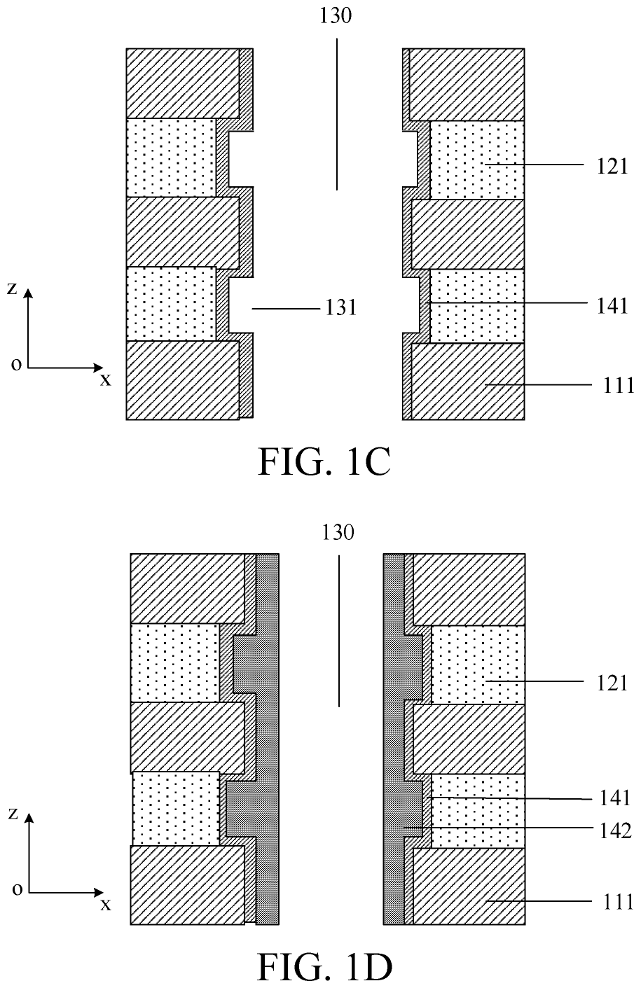

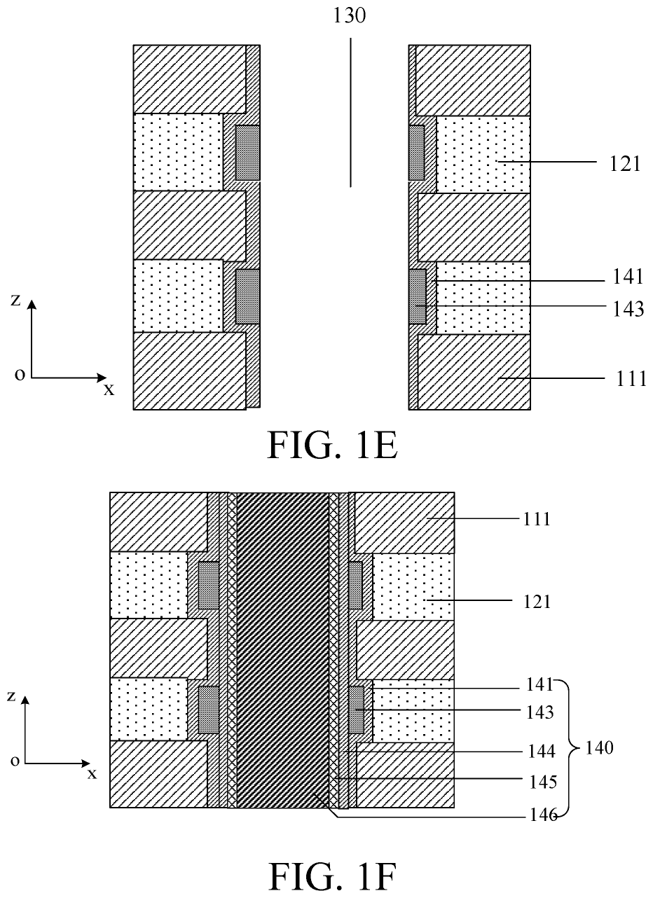

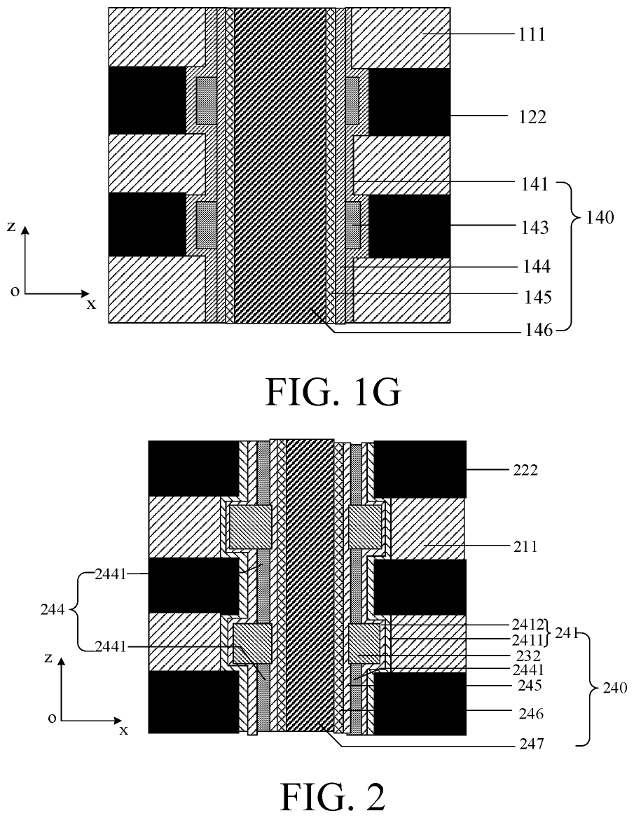

Referring to FIG. 1A, a laminated structure is formed. The laminated structure comprising alternating stacked dielectric layers 111 and sacrificial layers 121. The laminated structure can be formed on a substrate (not shown). The laminated structure is etched in a first direction (z direction) to form a plurality of channel holes 130 penetrating through the laminated structure. In some examples, the etching process may include: dry etching, wet etching or any combination thereof. The present disclosure does not limit the number and arrangement of the channel holes 130. For example, channel holes 130 may be arranged in any array.

In some examples, the constituent materials of the substrate may include: monoatomic semiconductor materials (such as silicon and germanium), III-V compound semiconductor materials, II-VI compound semiconductor materials, organic semiconductor materials or other semiconductor materials known in the art. The substrate can also be doped, for example p-doped or n-doped. The substrate in this example is a film structure with a certain thickness, which may include a bare wafer and an epitaxial layer as well. For example, the substrate is a bare wafer (for example, a bare silicon wafer) that has not been subjected to processes such as coating and etching. Alternatively, the substrate is an epitaxial layer grown epitaxially based on the surface of the bare wafer, and the material of the epitaxial layer can be the same as or different from that of the bare wafer. The bare wafer can be removed in a certain manufacturing process.

Referring to FIG. 1B, the sacrificial layers 121 are etched in a second direction (x direction), and the size of the sacrificial layers 121 in the x direction is reduced to form a void 131 between two adjacent dielectric layers 111. The opening of the void 131 faces the x direction. It is to be noted that the x direction here includes the positive x direction and the negative x direction.

Referring to FIG. 1C, a barrier layer 141 is formed on the sidewall of the channel hole 130 including the void 131. The barrier layer 141 extends into between two adjacent dielectric layers 111, and the barrier layer 141 does not fill the void 131.

Referring to FIG. 1D, a storage material layer 142 is formed on the sidewall of the channel hole 130 including the barrier layer 141 and the void 131. The storage material layer 142 fills the void 131, and the storage material layer 142 covers the surface of the barrier layer 141 in the x direction.

Referring to FIG. 1E, the storage material layer 142 is etched in the x direction, a portion of the storage material layer 142 on the surface of the barrier layer 141 is removed, and the storage material layer 142 in the void 131 is reserved to form a storage sublayer 143. Multiple discontinuous storage sublayers layers 143 are electrically isolated from each other and constitute storage layers of the three-dimensional memory. The surface of the storage sublayer 143 in the x direction may be flush with the barrier layer 141 or not.

Referring to FIG. 1F, a tunneling layer 144 and a channel layer 145 covering the storage layer and the barrier layer 141 are formed in sequence in the x direction. The channel hole 130 is filled with an insulating material to form a core 146 to support the channel column 140.

Referring to FIG. 1G, the sacrificial layers 121 in FIG. 1F are removed and replaced with a conductive material to form gate layers 122, and each of the gate layers 122 controls a storage sublayer 143 correspondingly. The gate layers 122 serve as word lines of the three-dimensional memory. In some examples, the constituent materials of the gate layers 122 may include conductive materials such as tungsten, gold, silver, copper, aluminum, titanium, nickel, chromium and the like.

In some examples, the constituent materials of the dielectric layers 111, the barrier layer 141, the tunneling layer 144 and the core 146 include, but are not limited to, insulating materials such as silicon oxide, silicon oxynitride, or aluminum oxide and the like. The constituent materials of the sacrificial layers 121 may include materials such as silicon nitride, polysilicon, and monocrystalline silicon and the like. The constituent materials of the storage layer (or the storage sublayer 143) may include silicon nitride. The constituent materials of the channel layer 145 may include but not limited to: semiconductor materials such as monocrystalline silicon and polysilicon and the like, and the channel layer 145 may have n-type doping or p-type doping. In the example of the present disclosure, in order to make each film layer has a greater difference in etching selectivity during the etching process, so as to achieve a better specific etching effect, the material selection of barrier layer 141, storage sublayer 143 and tunneling layer 144 in the x direction may comprise: silicon oxide, silicon nitride, and silicon oxide. The material selection of the dielectric layers 111 and sacrifice layer 121 may comprise: silicon oxide and silicon nitride. For example, when the sacrificial layers 121 in FIG. 1B is etched, the dielectric layers 111 may be etched little or not substantially. As another example, when the storage material layer 142 in FIG. 1E is etched, the barrier layer 141 may be etched little or not substantially to improve production yield of devices.

In some examples, the processes for forming the laminated structure, the barrier layer 141, the storage material layer 142, the tunneling layer 144, and the channel layer 145 may include any process known in the art, such as low-temperature chemical vapor deposition, low-pressure chemical vapor deposition, rapid thermal chemical vapor deposition, atomic layer deposition or plasma enhanced chemical vapor deposition and the like. The process for forming the gate layers 122 includes a physical deposition process in addition to the above chemical deposition process.

In some specific examples, as shown in FIG. 1G, the storage sublayer 143 will extend into a portion of the gate layers 122, occupying part of the space of the gate layers 122. Thus, the size of the gate layers 122 in the x direction will be reduced, and the carrying voltage will drop to a certain extent, which will reduce the control ability of the gate layers 122 on the storage sublayer 143 to a certain extent. As shown in FIG. 1B, on the one hand, etching the sacrificial layers 121 in the x direction to form the void 131 will lead to over-etching of the sacrificial layers 121, resulting in the inhomogeneous morphology and size (including but not limited to size in the x direction or y direction) of the void 131, and finally the inhomogeneous morphology and size of the storage sublayer 143 shown in FIG. 1G, which in turn leads to shift of threshold voltage of the portion of storage sublayer 143 and thus degrades the stability of the memory. On the other hand, after forming the void 131 shown in FIG. 1B, the dielectric layers 111 above and below the void 131 will collapse and deform to varying degrees due to the loss of support, resulting in uneven filling of the storage material inside. Void defects appear in FIG. 1G, which reduce the charge trapping performance of the storage sublayer 143 and degrade the stability of the memory.

In view of this, according to some aspects of the examples of the present disclosure, a three-dimensional memory is provided. With reference to FIG. 2, the three-dimensional memory includes:
a stack structure comprising alternating stacked gate layers 222 and dielectric layers 211;
a plurality of channel columns 240 penetrating the stack structure in a first direction (2 direction) and comprising: a barrier layer 241, a storage layer 244, a tunneling layer 245, and a channel layer 246 arranged in sequence; and
a plurality of isolation structures 232 located between the dielectric layers 211 and the tunneling layer 245 in a second direction (x direction) perpendicular to the first direction.

Wherein the isolation structures 232 penetrate at least a portion of the storage layer 244 in the second direction.

In some examples, referring to FIG. 2, the channel column 240 further includes a core 247, and a barrier layer 241, a storage layer 244, a tunneling layer 245, and a channel layer 246 are arranged in sequence around the core 247 in the x direction. The channel layer 246 may be in contact with the core 247, and the core 247 is used to support the channel column 240.

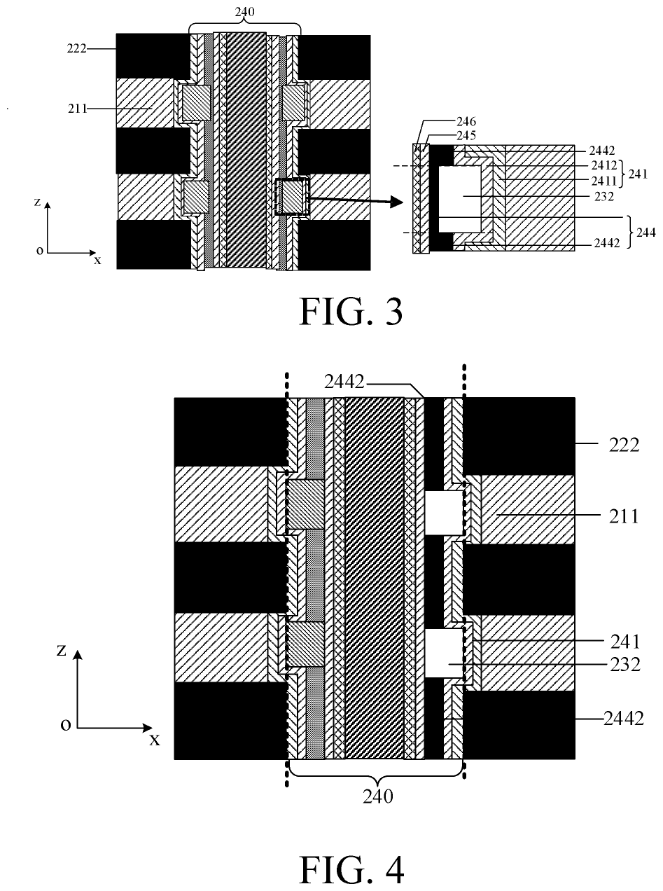

The first direction in the examples of the present disclosure may be the z direction in the drawings, and the second direction may be the x direction in the drawings. The isolation structures 232 shown in FIG. 2 penetrate the storage layer 244 in the x direction, and the storage layer 244 includes a plurality of first storage sublayers 2441. The isolation structures 232 shown in FIG. 3 penetrate a portion of thickness of the storage layer 244 in the x direction, the storage layer 244 includes a plurality of second storage sublayers 2442, and the first storage sublayer 2441 and the second storage sublayer 2442 correspond to the gate layers 222 in the x direction. The gate layers 222 control the storage sublayer to store or release electrons, which will be described in some examples as below.

In some examples, as shown in FIG. 2, the isolation structures 232 penetrate the storage layer 244 in the second direction. In some examples, the storage layer 244 is divided into a plurality of first storage sublayers 2441 by the isolation structures 232 in the first direction.

In some examples, referring to FIG. 3, the isolation structures 232 penetrate a portion of the thickness of the storage layer 244 in the second direction. A thickness of a portion of the storage layer 244 that is not penetrated by the isolation structures 232 in the second direction is smaller than a preset value. In some examples, a portion of the storage layer 244 between two of the isolation structures 232 that are adjacent in the first direction constitutes a second storage sublayer 2442.

The constituent material of the isolation structures 232 in the example of the present disclosure includes, but is not limited to, insulating materials such as silicon oxide, silicon nitride, silicon oxynitride, or aluminum oxide. The isolation structures 232 may penetrate the storage layer 244 in the x direction in FIG. 2 to divide the storage layer 244 into first storage sublayers 2441 that are discontinuous, electrically isolated, and capable of trapping electrons individually. Alternatively, as shown in FIG. 3, the isolation structures 232 penetrate only a portion of the thickness of the storage layer 244, and the thickness of remainder of the storage layer 244 is less than the minimum thickness of the film layer that can trap electrons. That is, the thickness of the portion of the storage layer 244 corresponding to the isolation structures 232 is less than a preset value such that it cannot trap electrons, and electrons cannot diffuse through this portion of the storage layer 244 with a small thickness. The thickness of the portion of the storage layer 244 between adjacent isolation structures 232 is not thinned and can still trap electrons Therefore, the isolation structures 232 can electrically divide the storage layer 244 into a plurality of second storage sublayers 2442 that can trap electrons individually.

In some examples, the aforementioned preset value may be determined according to the constituent material, density, or working condition of the storage layer 244, and different three-dimensional memories have different design requirements. For example, the storage layer 244 shown in FIG. 2 and FIG. 3 is a silicon nitride layer. The minimum thickness in the x direction of the silicon nitride layer that can trap electrons is 3 nm, and the aforementioned preset value is 3 nm. In some examples, the thickness of the silicon nitride layer in the x direction may range from 3 nm to 10 nm.

In some examples, the storage layer 244 shown in FIG. 2 is physically penetrated by the isolation structures 232. The storage layer 244 is a discontinuous film structure, and there is a relatively obvious physical boundary between the first storage sublayers 2441. At this time, the thickness of the first storage sublayer 2441 may be greater than or equal to 3 nm. Only a portion of the thickness of the storage layer 244 shown in FIG. 3 is penetrated by the isolation structures 232, thus the storage layer 244 is still a continuous film layer, and there is no obvious physical boundary between the second storage sublayers 2442. The second storage sublayer 2442 with electron trapping function and the portion of the storage layer 244 without electron trapping function can be distinguished by different thicknesses.

To explain the positions of the second storage sublayers 2442, a partial enlarged view of the channel column 240 is shown in FIG. 3. Dotted line is added to the partial enlarged view to divide the positions of the second storage sublayers 2442. No dotted line exists actually in the three-dimensional memory. Referring to FIG. 3, the storage layer 244 has at least two thicknesses in the x direction, where the second storage sublayer 2442 has a thickness greater than or equal to 3 nm, and the portion of the storage layer 244 with a thickness less than 3 nm has no electron trapping function. In some specific examples, the thickness of the first storage sublayer 2441 and the second storage sublayer 2442 may range from 3 nm to 10 nm. On the other hand, the entire storage layer 244 in FIG. 3 is orthographically projected in the x direction, and the physical film layer corresponding to the projection between the orthographical projections of two isolation structures 232 is the second storage sublayer 2442 of this example.

It is to be noted that the examples shown in FIG. 2 and FIG. 3 ignore the film thickness difference between the top and bottom of the channel column 240 caused by deposition processes such as ALD, and the thickness of the film layer at the top of the channel column 240 is greater than the thickness of the film layer at the bottom of the channel column 240.

In some examples, the constituent material of the isolation structures 232 includes but not limited to: insulating materials such as silicon oxide, silicon nitride, silicon oxynitride or aluminum oxide and the like, so as to better separate the storage layer 244.

In some examples, as shown in FIG. 2 and FIG. 3, the size in the first direction of a portion of the storage layer 244 between two of the isolation structures 232 that are adjacent in the first direction is greater than the size of the gate layers 222 in the first direction.

With reference to FIG. 2, the isolation structures 232 penetrate the storage layer 244 in the x direction to divide the storage layer 244 into a plurality of first storage sublayers 2441, and the length of the first storage sublayers 2441 in the z direction is greater than the thickness of the gate layers 222 in the z direction. On the one hand, while realizing that each gate layer 222 corresponds to a first storage sublayer 2441 in the x direction, it is also possible to increase the length of the first storage sublayer 2441 in the z direction to increase the facing area between the gate layers 222 and the storage sublayer in the x direction. As such, the control performance of the gate layers 222 can be improved, and the time to trap electrons and amount of electrons trapped by the storage sublayer are improved, thereby improving the stability of the memory. On the other hand, increasing the length of the first storage sublayer 2441 in the z direction does not increase the size (eg, diameter) of the channel columns 240 in the x direction, which is beneficial to maintaining a higher integration density of the channel columns 240.

Referring to FIG. 3, the isolation structures 232 penetrate a portion of thickness of the storage layer 244 in the x direction, and the storage layer 244 that is between the adjacent isolation structures 232 in the z direction and is not penetrated forms a second storage sublayer 2442. The length of the second storage sublayer 2442 in the z direction is greater than the thickness of the gate layers 222 in the z direction, which is conducive to improving the control performance of the gate layers 222, increasing the time to trap electrons and amount of electrons trapped by the storage sublayer, and improving the stability of memory, and is beneficial to maintaining a higher integration density of the channel columns 240.

In some examples, as shown in FIG. 2 and FIG. 3, the orthographic projection in the second direction of a portion of the storage layer 244 between two of the isolation structures 232 that are adjacent in the first direction overlaps at least partially with the orthographic projection of the gate layers 222 in the second direction.

In some examples, the orthographic projection in the x direction of the first storage sublayer 2441 and the second storage sublayer 2442 between two adjacent isolation structures 232 shown in FIG. 2 and FIG. 3 overlaps at least partially with the orthographic projection of the gate layers 222 in the x direction, so that each gate layer 222 can correspond to each storage sublayer, and the gate layers 222 control the storage sublayers corresponding thereto. The adjacent storage sublayers are electrically isolated by the isolation structures 232, thus reducing the mutual migration of electrons in the storage sublayer so as to improve the stability of the three-dimensional memory. Compared with filling material in the void 131 to form a storage sublayer as shown in FIG. 1C, the storage sublayers in the example of the present disclosure enables mutual electrical isolation to reduce leakage, while the storage sublayers do not need to be formed in the void, but only need to be formed on sidewalls of the channel holes 24, thus achieving better uniformity, which is beneficial to maintaining good electronic trapping performance of the storage sublayer and improving the stability of the three-dimensional memory. The storage sublayers mentioned in the example of the present disclosure include the first storage sublayer 2441 in FIG. 2 and the second storage sublayer 2442 in FIG. 3.

In some examples, as shown in FIG. 2 and FIG. 3, the orthographic projection in the x direction of the isolation structures 232 falls within the orthographic projection of the dielectric layers 211 in the x direction.

In some examples, as shown in FIG. 2 and FIG. 3, the orthographic projection in the x direction of the gate layers 222 falls between the orthographic projections in the x direction of two isolation structures 232 that are adjacent in the z direction.

In this structural layout, the gate layers 222 can all participate in controlling the storage sublayer in the x direction, which can increase the load voltage range of the gate layers 222 and can maximize the facing area between the gate layers 222 and the storage sublayers in the x direction. The control performance of the gate layers 222 is improved, and the time to trap electrons and amount of electrons trapped by the storage sublayer are improved, thereby improving the stability of the memory.

In some examples, the isolation structures 232 in FIG. 2 and FIG. 3 can be shifted up and down in the z direction, reserving a portion of the storage layer 244 with charge trapping capability corresponding to each gate layer 222, so that the gate layers 222 control the storage sublayer. It can be understood that isolation structures 232 can be shifted up and down to occupy part of the space of the gate layers 222. Compared with FIG. 2 and FIG. 3, the gate layers 222 and the storage sublayer of this example can reduce the difficulty of aligning the isolation structures 232 with the dielectric layers 211, reducing the fabrication difficulty and improving the process window while maintaining good performance of the gate layers 222 and the storage sublayer.

In some examples, the isolation structures 232 shown in FIG. 2 and FIG. 3 may penetrate a portion of the barrier layer 241 in the x direction, or completely penetrate the barrier layer 241 and extend into the dielectric layers 211. The barrier layer 241 includes an insulating material, and may be a single-layer film structure, or may include a multi-layer composite film structure.

In some other examples, the barrier layer 241 shown in FIG. 2 and FIG. 3 may include a first barrier sublayer 2411 and a second barrier sublayer 2412. The first barrier sublayer 2411 surrounds the second barrier sublayer 2412, the first barrier sublayer 2411 is located between the second barrier sublayer 2412 and the stacked structure in the x direction, and the second barrier sublayer 2412 is located between the first barrier sublayer 2411 and the storage layer 244. The isolation structures 232 can partially penetrate or completely the second barrier sublayer 2412. The isolation structures 232 may penetrate the second barrier sublayer 2412 and then penetrate partially or completely the first barrier sublayer 2411. In some examples, the isolation structures 232 do not penetrate the barrier layer 241 and extend into the dielectric layers 211, and are surrounded by the barrier layer 241. In some examples, the isolation structures 232 may also penetrate the barrier layer 241 and extend into the dielectric layers 211.

As an example, the second barrier sublayer 2412 may include insulating materials such as silicon oxide and silicon oxynitride and the like, and the first barrier sublayer 2411 may include high dielectric materials such as aluminum oxide and the like, so as to improve the insulating performance of the barrier layer 241 and reduce the leakage of gate layers 222. Furthermore, the first barrier sublayer 2411 can be used to protect the channel column 240 during the fabrication of the gate layers 222 and prevent etching damage to the channel column 240 by the etchant.

In some examples, after penetrating the storage layer 244 in the x direction, the isolation structures 232 shown in FIG. 2 may continue to extend in the x direction, penetrating or partially penetrating the tunneling layer 245, but not extending into the channel layer 246. The tunneling layer 245 is used for electron tunneling between the storage sublayer corresponding to the gate layers 222 and the channel layer 246 and is further used to prevent the storage sublayer from leaking when not performing operations. Therefore, the actual active area of tunneling layer 245 is the area corresponding to the gate layers 222 in the x direction, and the isolation structures 232 do not occupy the space of the gate layers 222. As a result, extending the isolation structures 232 into the barrier layer will not reduce the stability of the memory.

The isolation structures 232 in the example of the present disclosure are provided in correspondence with the dielectric layers 211, and the setting of the isolation structures 232 will not change the thickness uniformity of the storage sublayer. On the premise that the storage sublayer corresponds to the gate layers 222, the isolation structures 232 can extend in the x direction, and the isolation structures 232 do not extend into the channel layer 246, so that the manufacturing difficulty of the isolation structures 232 can be reduced.

In some examples, as shown in FIG. 2 and FIG. 3, the isolation structures 232 extend toward the dielectric layers 211, and a part of the isolation structures 232 extends into between two adjacent gate layers 222. In this example, the isolation structures 232 extend into between the two gate layers 222 in the x direction. The isolation structures 232 will not occupy the space of the gate layers 222 and will not destroy the morphology of the storage sublayer, which enables the size of the isolation structures 232 in the x direction to be increased while maintains good uniformity of film thickness of the storage sublayer, thereby improving the electrical isolation performance of the storage sublayer. When the isolation structures 232 extends into between two adjacent gate layers 222, it may partially or completely penetrate the barrier layer 241.

In some other examples, the isolation structures 232 may not extend into the dielectric layers 211. That is, the isolation structures 232 do not occupy the location space of the dielectric layers 211. For example, with the three-dimensional memory shown in FIG. 4, the orthographic projection in z direction of the isolation structures 232 has no overlapping portion with the orthographic projection in z direction of the gate layers 222 according to this example, which is different from that shown in FIG. 2 and FIG. 3 where the orthographic projection in the z direction of the isolation structures 232 has an overlapping portion with the orthographic projection in the z direction of the gate layers 222. The size of the isolation structures 232 in the x direction as shown in FIG. 4 may be less than the size of the isolation structures 232 in the x direction as shown in FIGS. 2 and 3, which is beneficial to reducing the size of the channel column 240 in the x direction and improving the integration degree of the three-dimensional memory.

In some examples, the barrier layer 241 is located between the dielectric layers 211 and the isolation structures 232, and the portion of the isolation structures 232 extending into the dielectric layers 211 is surrounded by the barrier layer 241.

In this example, the isolation structures 232 do not penetrate the barrier layer 241, and the barrier layer 241 is a continuous film layer structure. In some further examples, the isolation structures 232 may partially or completely penetrate the barrier layer 241 in x direction, and the isolation structures do not occupy the space of the gate layers 222, which is conducive to maintaining the uniformity of the structure of the gate layers 222 and is conducive to maintaining good stability of the three-dimensional memory. The isolation structures 232 and the barrier layer 241 may have a relatively obvious physical boundary. When the barrier layer 241 does not completely penetrate the barrier layer 241, and when the material composition and film layer density of the isolation structures 232 and the barrier layer 241 are the same or similar, especially after high-temperature annealing is performed to eliminate film stress and repair defects, there may be no obvious physical boundary between the isolation structures 232 and the barrier layer 241.

In some examples, the barrier layer 241 includes a first barrier sublayer 2411 and a second barrier sublayer 2412. The second barrier sublayer 2412 is located between the first barrier sublayer 2411 and the storage layer 244, and the first barrier sublayer 2411 includes high dielectric materials.

In some examples, the first barrier sublayer 2411 includes aluminum oxide material, and the second barrier sublayer 2412 includes silicon oxide material.

The dielectric constant of the first barrier sublayer 2411 may be greater than that of the second barrier sublayer 2412. When achieving the same insulation performance, the high dielectric material can have a smaller film thickness, thereby reducing the total thickness of the barrier layer 241 and improving the integration density of the channel column 240. In some examples, the first barrier sublayer 2411 may include high dielectric materials such as aluminum oxide and the like, and the second insulating layer may include common silicon oxide. The first barrier sublayer 2411 may also be used as an etching protection layer during the fabrication of the gate layers 222 to protect the channel column 240 and prevent etching damage to the channel column 240 by the etchant.

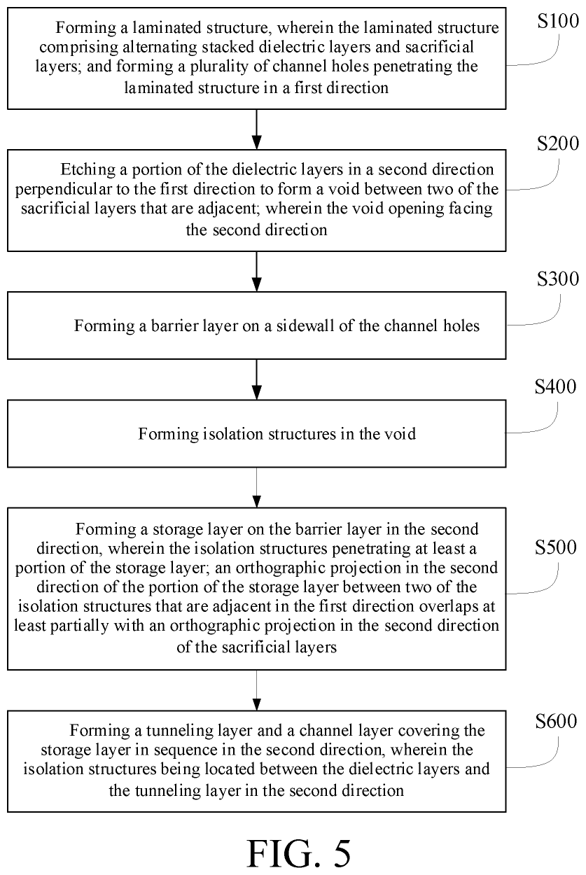

According to some aspects of the examples of the present disclosure, a manufacturing method of a three-dimensional memory is provided. As shown in FIG. 5, the manufacturing method includes:
forming a laminated structure, wherein the laminated structure comprising alternating stacked dielectric layers and sacrificial layers; and forming a plurality of channel holes penetrating the laminated structure in a first direction;
etching a portion of the dielectric layers through the channel holes in a second direction perpendicular to the first direction to form a void between two of the sacrificial layers that are adjacent;
forming a barrier layer on a sidewall of the channel holes;
forming isolation structures in the void;
forming a storage layer on the barrier layer in the second direction, wherein the isolation structures penetrating at least a portion of the storage layer; an orthographic projection in the second direction of the portion of the storage layer between two of the isolation structures that are adjacent in the first direction overlaps at least partially with an orthographic projection in the second direction of the sacrificial layers; and
forming a tunneling layer and a channel layer covering the storage layer in sequence in the second direction, wherein the isolation structures being located between the dielectric layers and the tunneling layer in the second direction.

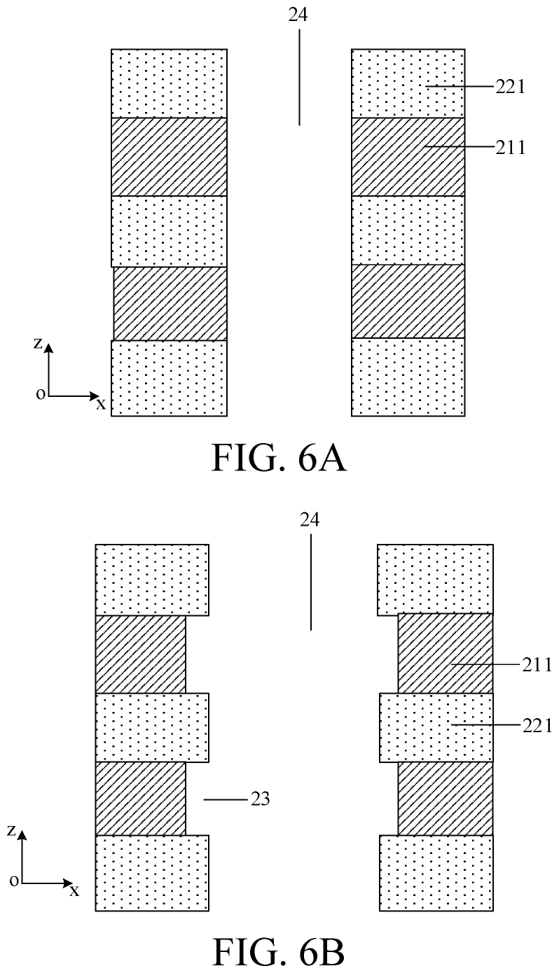

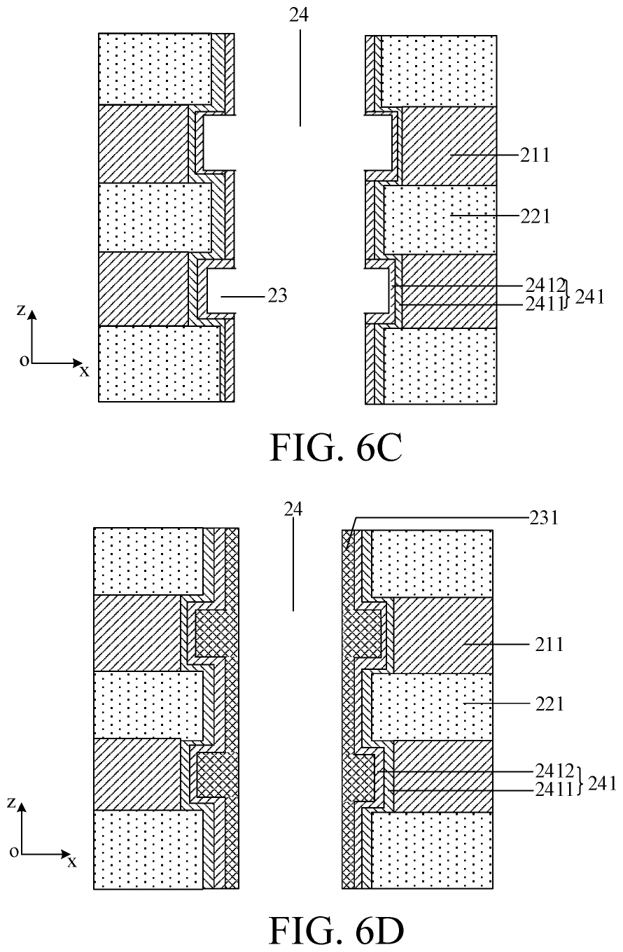

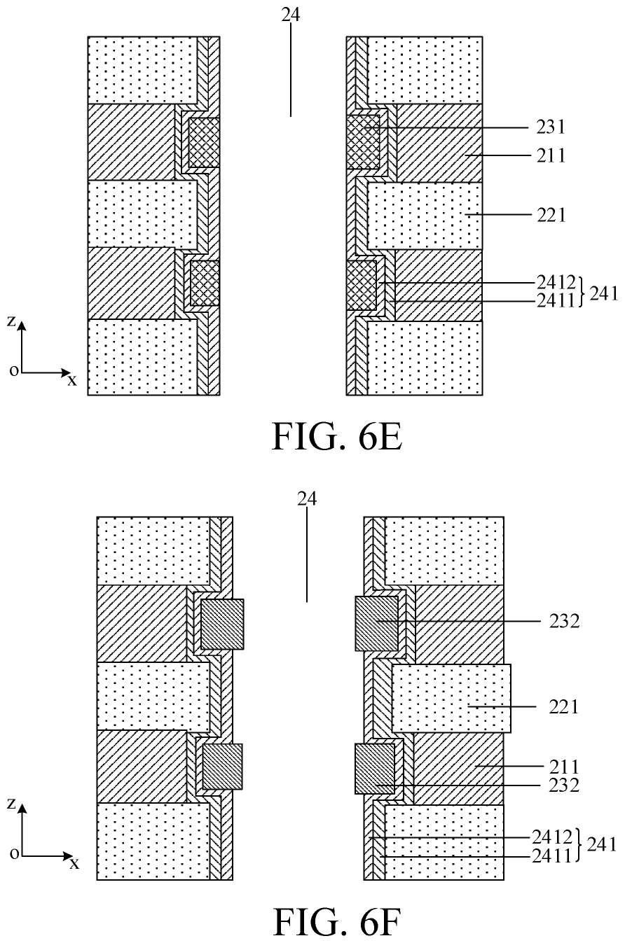

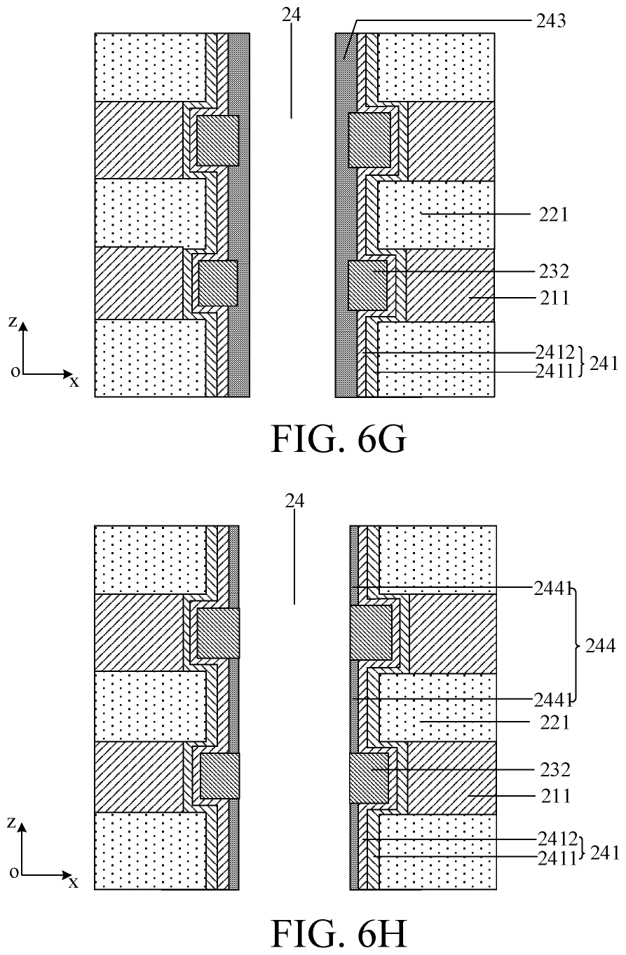

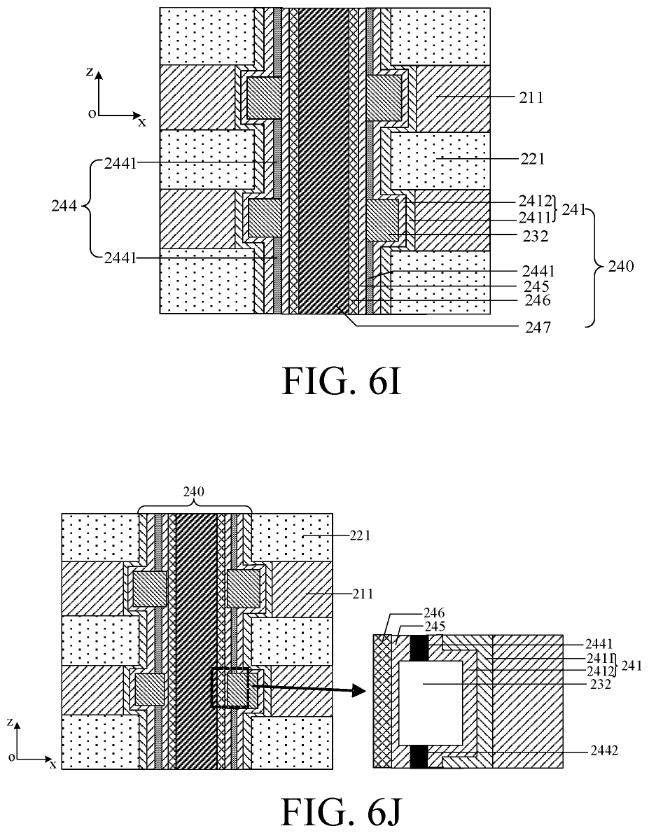

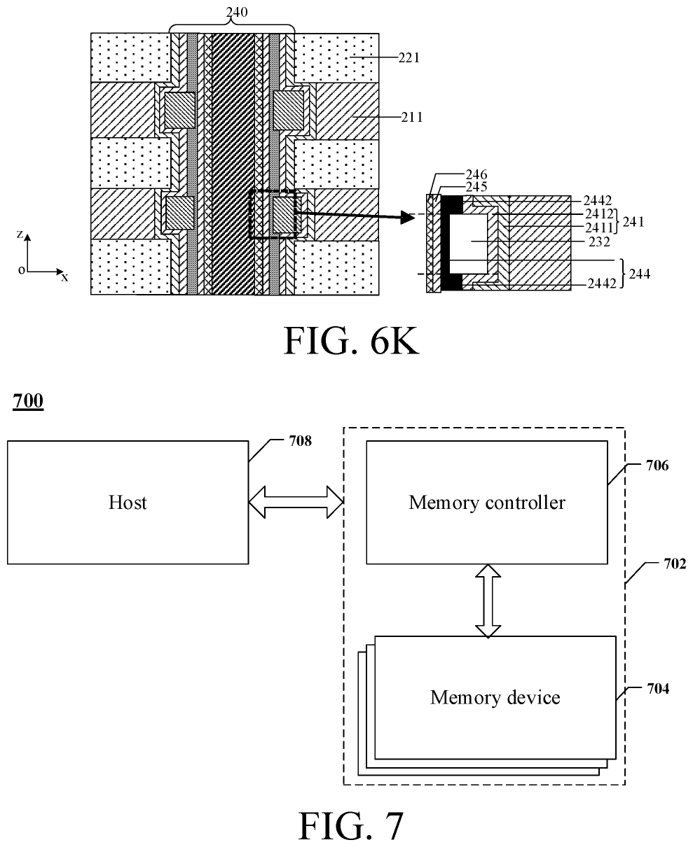

In some examples, as shown in FIG. 6A, dielectric layers 211 and sacrificial layers 221 may be alternately deposited on the substrate to form the laminated structure. The material of the dielectric layers 211 may include silicon oxide, and the material of the sacrificial layers 221 may include silicon nitride. The channel holes 24 penetrating through the laminated structure are then formed in the z direction. The example of the present disclosure does not limit the number and arrangement of the channel holes 24.

Referring to FIG. 6B, the dielectric layers 211 are etched along the x direction through the channel hole 24 to reduce the size of the dielectric layers 211 in the x direction, so that a void 23 is formed between two adjacent sacrificial layers 221. The opening of the void 23 faces the x direction, and the x direction may include the x positive direction and the x negative direction. Etching processes may include, but not limited to: dry etching, wet etching, or combinations thereof. In some specific examples, the dielectric layers 211 may comprise silicon oxide, and the sacrificial layers 221 may comprise silicon nitride. The silicon oxide is etched with an etching solution including hydrofluoric acid, and the etching rate of silicon nitride in hydrofluoric acid is much low than that of silicon oxide, or silicon nitride is substantially not etched in hydrofluoric acid, which can protect the sacrificial layers 221 from being etched while forming the void 23 and maintain the good morphology of the sacrificial layers 221. Thus, the gate layers 222 still have a better morphology after the sacrificial layers 221 are replaced with the gate layers 222, which improves the manufacturing yield of the device. Compared with dry etching, wet etching in this example has a lower manufacturing cost, and the size of the void 23 in the x direction can be controlled by the etching time. The longer the etching time, the larger the size of the void 23 in the x direction, namely, the deeper the void 23 extends into the dielectric layers 211.

Referring to FIG. 6C, the sidewall of the channel hole 24 including the void 23 in FIG. 6B is deposited to form a barrier layer 241. The barrier layer 241 may include a single-layer film or a multi-layer film structure, and the barrier layer 241 may cover the sidewalls of the sacrificial layers 221 and the inner walls of the void 23. It can be understood that, in some specific examples, the sacrificial layers 221 will be subsequently replaced with conductive gate layers 222 for controlling the storage layer 244 with reference to FIG. 2 and FIG. 3. The barrier layer 241 is used as a gate dielectric layer to electrically isolate the gate layers 222 and the storage sublayer. Therefore, the barrier layer 241 may only cover the side of the sacrificial layers 221 through a selective deposition process, and the barrier layer 241 does not cover the inner wall of the void 23, according to the example of the present disclosure. At this time, the barrier layer 241 is a discontinuous film structure. As an example, a reactive gas that is compatible with the sacrificial layers 221 and is not compatible with the dielectric layers 211 may be adopted, and the barrier layer 241 may be selectively deposited only on the sidewall of the sacrificial layers 221. The sacrificial layers 221 may include nitride silicon, and the dielectric layers 211 may include silicon oxide. The constituent material of the barrier layer 241 includes, but is not limited to, insulating materials such as silicon oxide, silicon nitride, silicon oxynitride, or silicon oxide and the like.

In some examples, an example is described with reference to FIG. 6C, wherein forming the barrier layer 241 includes:
forming a first barrier sublayer 2411 on the sidewall of the channel hole 24 comprising the void 23 shown in FIG. 6B;
forming a second barrier sublayer 2412 covering the first barrier sublayer 2411; the dielectric constant of the first barrier sublayer 2411 may be greater than that of the second barrier sublayer 2412. In this example, the first barrier sublayer 2411 may include high dielectric materials such as aluminum oxide and the like, and the second barrier sublayer 2412 may include silicon oxide. The high dielectric material can also reduce the total thickness of the barrier layer 241 while maintaining or improving the insulation performance, which is beneficial to improving the integration degree.

In some examples, the method of forming isolation structures 232 includes:
forming isolation material layers 231 covering the barrier layer 241 and filling the void 23, with reference to FIG. 6D;
removing a portion of the isolation material layers 231 covering the barrier layer 241, with reference to FIG. 6E; and
oxidizing remainder of the isolation material layers 231 to form the isolation structures 232, with reference to FIG. 6F.

In FIG. 6E, the barrier layer 241 can be exposed after the isolation material layers 231 covering the barrier layer 241 is removed by etching, so that the sacrificial layers 221 do not have corresponding isolation material layers 231 in the x direction, which is convenient for the subsequent formation of the storage layer 244 and also facilitates the subsequent control over the storage sublayer by the gate layers 222. In this example, the surface of the isolation material layers 231 in the x direction after etching is flush with the surface of the barrier layer 241 in the x direction. According to further examples, over-etching is performed to make the surface of remainder of the isolation material layers 231 in the x direction is lower than the surface of the barrier layer 241 in the x direction. When the isolation material layers 231 is oxidized, the size of the isolation material layers 231 in the x direction will be increased. The size of the isolation structures 232 generated in FIG. 6F in the x direction may be greater than that of the isolation material layers 231 shown in FIG. 6E, and the surface of the isolation structures 232 in the x direction protrudes from the surface of the barrier layer 241 in the x direction.

In some examples, the constituent material of the isolation material layers 231 as shown in FIG. 6D and FIG. 6E includes at least one of: monocrystalline silicon, polysilicon and amorphous silicon. Silicon in the isolation material layers 231 is oxidized to form silicon oxide, so that the isolation material grows in the x direction to form isolation structures 232 including silicon oxide. In this example, the composition of the isolation material layers 231 is only an example and may include materials such as germanium, aluminum, and the like. After the isolation material layers 231 is oxidized, an insulating oxide is formed to form the isolation structures 232. The longer the oxidation time, the greater the size of the isolation structures 232 in the x direction. The oxidation process may include a tubular furnace or a thermal oxidation process in a reaction chamber. It is to be noted that, in this example, the isolation material layers 231 can all participate in the oxidation reaction, that is, all silicon is oxidized into silicon oxide. Alternatively, a part of the isolation material layers 231 participates in the oxidation reaction, that is, a part of the silicon exposed on the sidewall of the channel hole 24 is oxidized into silicon oxide, and the remainder is still silicon.

In some examples, the manufacturing method shown in FIG. 6E to FIG. 6F according to the examples of the present disclosure can be carried out by using a selective deposition process in addition to the oxidation process. For example, the material of the isolation material layers 231 in FIG. 6E is different from the material of the barrier layer 241. During the deposition process, the reactive gas that is compatible with the isolation material layers 231 is selected to react with the isolation material layers 231 to form the isolation structures 232, while the barrier layer 241 is incompatible or non-reactive with the reactive gas such that the surface of the barrier layer 241 will not undergo a film-forming reaction. Similar to the scheme in which the isolation structures 232 is formed by oxidizing the isolation material layers 231 in the previous examples, a portion of the isolation material layer 231 participates in the film-forming reaction, or the entire isolation material layers 231 participates in the film-forming reaction, during the selective deposition process.

In some examples, during the deposition process for forming the isolation structures 232, the isolation material layers 231 may not participate in the film-forming reaction. For example, an activation gas compatible with the isolation material layers 231 and not incompatible with the barrier layer 241 is supplied into the channel hole 24 before the deposition reaction. Afterwards, the reaction gas for deposition is introduced, and the activation gas plays a catalytic role in the deposition reaction to accelerate the film-forming reaction on the isolation material layers 231, so that the isolation structures 232 is formed on the side of the isolation material layers 231 exposed to the channel hole 24. The barrier layer 241 is not formed or substantially not formed, and even a little material layer formed on the barrier layer 241 can be removed by an etching process. At this time, the isolation structures 232 and the isolation material layers 231 are two separate structures, which are not shown in the drawings.

In some examples, the size of the void 23 in the x direction can be adjusted by adjusting the etching parameters in FIG. 6B. When the size of the void 23 in the x direction is larger, the void 23 may extend into the dielectric layers 211 to a greater depth such that the orthographic projection in the z direction of the isolation structures 232 formed in FIG. 6E overlaps with the orthographic projection in the z direction of the sacrificial layers 221. In some other examples, the depth of the void 23 extending into the dielectric layers 211 is smaller such that the orthographic projection in the z direction of the formed isolation structures 232 does not overlap with the orthographic projection in the z direction of the sacrificial layers 221, and the resulting three-dimensional memory structure is exemplified in FIG. 4.

In some examples, as shown in FIG. 6F, the orthographic projection in the x direction of the isolation structures 232 falls within the orthographic projection in the second direction of the dielectric layers 211.

In this example, the isolation structures 232 correspond to the dielectric layers 211 and are formed between two sacrificial layers 221 that are adjacent in the z direction. The isolation structures 232 do not occupy the space of the sacrificial layers 221, so that the gate layers 222 formed by the subsequent replacement of the sacrificial layers 221 have a better morphology and a larger size, which is conducive to increasing the load voltage of the gate layers 222 and improving the stability of the device.

In some examples, the method of forming the storage layer 244 includes:
forming a storage material layer 243 covering the barrier layer 241 and the isolation structures 232, with reference to FIG. 6G; and
etching the storage material layer 243 to expose the isolation structures 232 to form the storage layer 244, with reference to FIG. 6H, wherein the storage layer 244 being divided into a plurality of first storage sublayers 2441 by the isolation structures 232.

In FIG. 6G, the isolation structures 232 protrudes from the surface of the barrier layer 241 in the x direction, and the deposited storage material layer 243 covers the surface of the barrier layer 241 and the surface of the isolation structures 232, so that a part of the isolation structures 232 extends into the storage material layer 243. In FIG. 6H, a part of the storage material layer 243 is etched through the channel hole 24 to reduce its thickness in the x direction until the isolation structures 232 is exposed, and the original continuous storage layer 244 is penetrated by the isolation structures 232 and divided into a plurality of first storage sublayers 2441. The storage sublayer includes silicon nitride, and its thickness in the x direction may be greater than or equal to 3 nm.

In this example, the planes of the isolation structures 232 and the first storage sublayer 2441 can be flush in the x direction. Referring to FIG. 6I, the tunneling layer 245 and channel layer 246 are formed in sequence in the x direction, the isolation structures 232 are located between the dielectric layers 211 and the tunneling layer 245 in the x direction, and the isolation structures 232 do not extend into the tunneling layer 245. In some examples, the tunneling layer 245 includes insulating materials such as silicon oxide and silicon oxynitride and the like. The channel layer 246 includes semiconductor materials such as monocrystalline silicon and polysilicon and the like.

In some examples, when the storage material layer 243 shown in FIG. 6G is etched, the storage material layer 243 may be over-etched to remove the isolation material layers 243 on the barrier layer 241. When the isolation structures 232 penetrates the storage layer 244 to form the first storage sublayer 2441, it also protrudes from the surface of the first storage sublayer 2441 in the x direction, the tunneling layer 245 formed thereafter is shown in FIG. 6J, and the isolation structures 232 extend into the tunneling layer 245 in the x direction. The tunneling layer 245 is used for electron tunneling between the storage sublayer corresponding to the gate layers 222 and the channel layer 246 and is also used to prevent the storage sublayer from leaking when not performing operations. Therefore, the actual active area of the tunneling layer 245 is the area corresponding to the gate layers 222 in the x direction, and the isolation structures 232 do not occupy the space of the gate layers 222, so the extension of the isolation structures 232 into the barrier layer will not reduce the stability of the memory. The process window of the etching process in FIG. 6G may be increased to reduce the manufacture difficulty.

In some examples, the method of forming the storage layer 244 includes:
forming a storage material layer 243 covering the barrier layer 241 and the isolation structures 232, with reference to FIG. 6G;
etching the storage material layer 243 to reduce its thickness in the x direction such that the thickness of a region of the formed storage layer 244 corresponding to the isolation structures 232 in the second direction is smaller than a preset value; wherein a portion of the storage layer 244 between two of the isolation structures that are adjacent in the z direction forming a second storage sublayer 2442. In some examples, the preset value may be 3 nm. The aforementioned preset value can be determined according to the constituent material, density, or working condition of the storage layer 244, and different three-dimensional memories have different design requirements.

Referring to FIG. 6K, etch amount of the storage material layer 243 is reduced by adjusting process parameters such as etching time and the like, so that the storage material layer 243 does not expose the isolation structures 232. The thickness of the storage material layer 243 shown in FIG. 6G in the x direction is greater than or equal to a preset value. After the etching is completed, the thickness of remainder of the storage material layer 243 corresponding to the isolation structures 232 in the x direction is smaller than the preset value. That portion of the storage material layer 243 is too thin to trap electrons. Different from the discontinuous storage layer 244 shown in FIGS. 6h to 6j, the storage layer 244 in FIG. 6K is a continuous film layer, and there is no obvious physical boundary between the second storage sublayers 2442. A distinction can be made between the second storage sublayer 2442 with the electron trapping function and the portion of the storage layer 244 without the electron trapping function by different thicknesses. The storage layer 244 has at least two thicknesses in the x direction. The second storage sublayer 2442 has a thickness greater than or equal to 3 nm, and the portion of the storage layer 244 with a thickness less than 3 nm has no electron trapping function. On the other hand, the entire storage layer 244 in FIG. 3 is orthographically projected in the x direction, and the physical film layer corresponding to the projection between orthographical projects of the two isolation structures 232 is the second storage sublayer 2442 of this example. It is to be noted that, in the example of the present disclosure, the film thickness difference between the top and bottom of the channel column 240 caused by deposition processes such as ALD and the like is ignored, and the film thickness at the top of the channel column 240 is greater than the film thickness at the bottom of the channel column 240.

In some examples, as shown in FIG. 6H and FIG. 6K, the size in the first direction of a portion of the storage layer 244 between two isolation structures 232 adjacent in the first direction is greater than the size of the gate layers 222 in the first direction.

As shown in FIG. 6H, the storage layer 244 is penetrated by the isolation structures 232 in the x direction to form the first storage sublayer 2441, and the length of the first storage sublayer 2441 in the z direction is greater than the thickness of the gate layers 222 in the z direction. On the one hand, while realizing that each gate layer 222 corresponds to a first storage sublayer 2441 in the x direction, it is possible to increase the length of the first storage sublayer 2441 in the z direction to increase the facing area between the gate layers 222 and the storage sublayer in the x direction, to thereby improve the control performance of the gate layers 222, improve the time to trap electrons and amount of electrons trapped by the storage sublayer, and improve the stability of the memory. On the other hand, increasing the length of the first storage sublayer 2441 in the z direction does not increase the size (e.g., diameter) of the channel columns 240 in the x direction, which is conducive to maintaining a higher integration density of the channel columns 240.

Referring to FIG. 6K, the isolation structures 232 penetrates a portion of the thickness of the storage layer 244 in the x direction, and the storage layer 244 that is not penetrated and is between isolation structures 232 adjacent in the z direction forms a second storage sublayer 2442. The length of the second storage sublayer 2442 in the z direction is greater than the thickness of the gate layers 222 in the z direction, which is conducive to improving the control performance of the gate layers 222, improving the time to trap electrons and amount of electrons trapped by the storage sublayer, and improving the stability of memory, and thus is beneficial to maintaining a higher integration density of the channel columns 240.

In some examples, as shown in FIG. 6I, after the channel layer 246 is fabricated, remainder of the space of the channel hole 24 is filled with an insulating material to form a core 247 for supporting the channel column 240.

In some examples, the manufacturing method further includes: replacing the sacrificial layers 221 with a conductive material to form the gate layers 222. In some examples, the sacrificial layers 221 is removed by etching first, a cavity is formed between adjacent dielectric layers 211, and the cavity is filled with a conductive material to form the gate layers 222. The constituent material of the gate layers 222 includes but not limited to conductive materials such as tungsten, gold, silver, copper, aluminum, titanium, nickel, chromium and the like. In some examples, the sacrificial layers 221 in FIG. 6I is replaced with gate layers 222 to form the three-dimensional memory shown in FIG. 2, and the sacrificial layers 221 in FIG. 6K is replaced with the gate layers 222 to form the three-dimensional memory shown in FIG. 3.

According to some aspects of the examples of the present disclosure, a memory system is provided, including:
a memory device including one or more three-dimensional memories as described in the above examples; and
a memory controller coupled to the memory device and configured to control the memory device.

FIG. 7 illustrates a block diagram of an example system 700 having a memory device, according to some aspects of the example of the present disclosure. System 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 7, system 700 can include a host 708 and a memory system 702 having one or more memory device 704 and a memory controller 706. Host 708 can be a processor of an electronic device, such as a central processing unit (CPU), or a system-on-chip (SoC), such as an application processor (AP). Host 708 can be configured to send or receive data to or from memory device 704.

Memory device 704 may be any memory disclosed in this disclosure. As disclosed in detail below, the memory device 704 (e.g., a NAND flash memory (e.g., three-dimensional (3D) NAND flash memory)) may have reduced leakage current from drive transistors (e.g., string drivers) coupled to unselected word lines during an erase operation, which allows further scaling down of the size of the drive transistors.

Memory controller 706 is coupled to memory device 704 and host 708 and is configured to control memory device 704, according to some examples. Memory controller 706 can manage the data stored in memory device 704 and communicate with host 708.

In some examples, memory controller 706 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some examples, memory controller 706 is designed for operating in a high duty-cycle environment solid state disks (SSD) or embedded multi-media-cards (eMMCs) used as data storage for mobile devices, such as smartphones, tablets, laptop computers, etc., and enterprise storage arrays. Memory controller 706 can be configured to control operations of memory device 704, such as read, erase, and program operations. Memory controller 706 can also be configured to manage various functions with respect to the data stored or to be stored in memory device 704 including, but not limited to bad-block management, garbage collection, logical-to-physical address conversion, wear leveling, etc.

In some examples, memory controller 706 is further configured to process error correction codes (ECCs) with respect to the data read from or written to memory device 704. Any other suitable functions may be performed by memory controller 706 as well, for example, formatting memory device 704. Memory controller 706 can communicate with an external device (e.g., host 708) according to a particular communication protocol. For example, memory controller 706 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

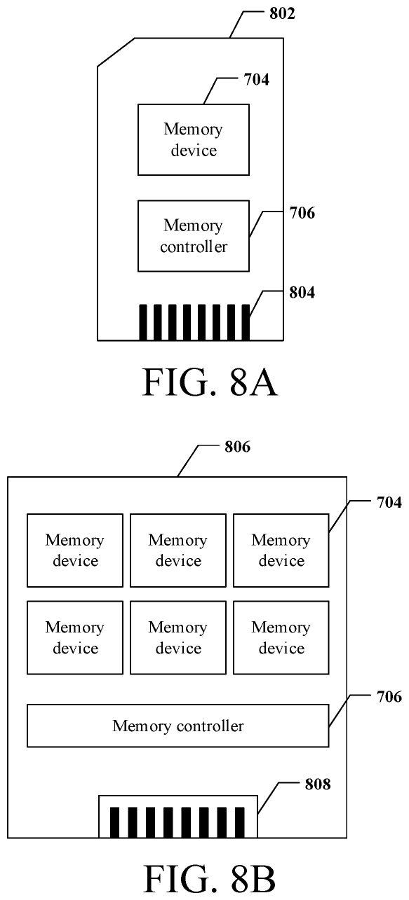

Memory controller 706 and one or more memory device 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 8A, memory controller 706 and a single memory device 704 may be integrated into a memory card 802. Memory card 802 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 802 can further include a memory card connector 804 coupling memory card 802 with a host (e.g., host 708 in FIG. 7). In another example as shown in FIG. 8B, memory controller 706 and multiple memory devices 704 may be integrated into an SSD 806. SSD 806 can further include an SSD connector 808 coupling SSD 806 with a host (e.g., host 708 in FIG. 7). In some examples, at least one of the storage capacity or the operation speed of SSD 806 is greater than those of memory card 802. The example of the present disclosure does not limit the form of the package of the memory controller and the memory device and execution protocol, which can be selected and optimized according to the host interface protocol and the actual needs of users.

In some examples, the memory device may include a memory array and peripheral circuits, and the memory array and peripheral circuits may be disposed on the same wafer. That is, the memory array and peripheral circuits are disposed on the same die to form a chip. The memory array and the peripheral circuits can be respectively disposed on different dies. In other words, a die with memory array and a die with peripheral circuit form a chip by means of hybrid bonding. The die mentioned in the example of the present disclosure takes the storage array as the division object, one die may or may not include the peripheral circuit, and the memory array may include multiple dies. A die of the memory array includes at least one plane. Adjacent planes can be divided by cutting lines. Each plane can include multiple pages. The memory cells on each page share word lines. Each page can be used as the smallest unit of read and write operations. Each plane can be divided into multiple blocks, and each block can be used as the smallest unit of an erase operation. A memory device may include one die or multiple dies. A memory device may include multiple memory arrays.

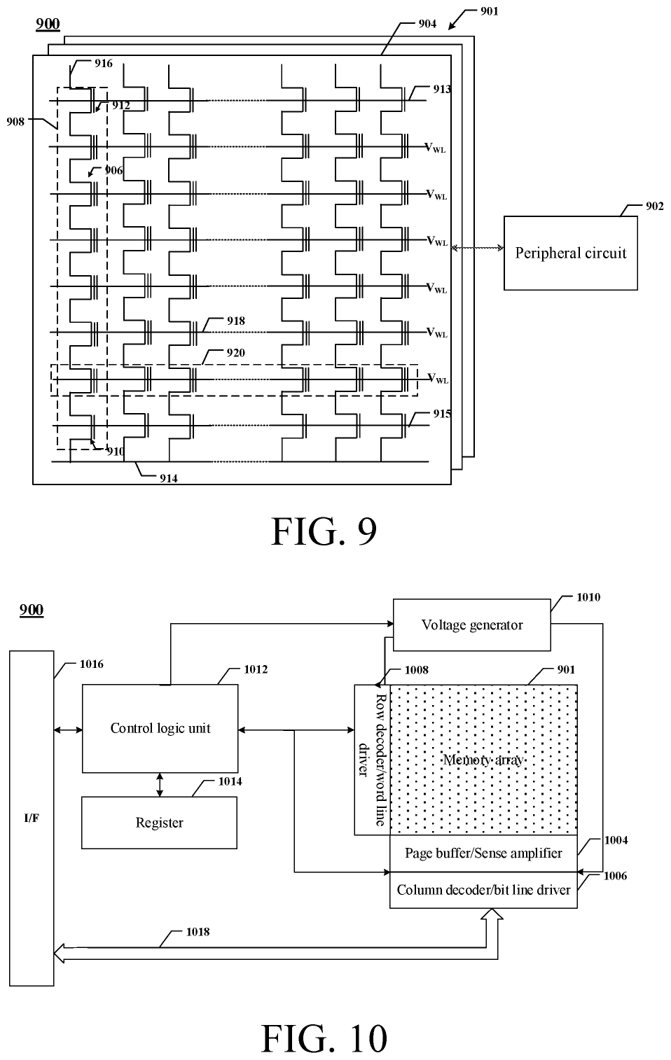

FIG. 9 illustrates a schematic circuit diagram of example memory device 900 including peripheral circuits, according to some aspects of the example of the present disclosure. Memory device 900 can be an example of memory device 704 in FIG. 7. Memory 900 can include a memory array 901 and peripheral circuits 902 coupled to memory cell array 901. The memory array 901 can comprise an NAND flash memory array, in which memory cells 906 are provided in the form of an array of NAND memory strings 908 each extending vertically above a substrate (not shown).

In some examples, each NAND memory string 908 includes a plurality of memory cells 906 coupled in series and stacked vertically. Each memory cell 906 can hold a continuous, analog value, such as an electrical voltage or charge, that depends on the number of electrons trapped within a region of memory cell 906. Each memory cell 906 can be either a floating gate type of memory cell including a floating-gate transistor or a charge trap type of memory cell including a charge trap transistor.

In some examples, each memory cell 906 is a single-level cell (SLC) that has two possible memory states and thus, can store one bit of data. For example, the first memory state “0” can correspond to a first range of voltages, and the second memory state “1” can correspond to a second range of voltages. In some examples, each memory cell 906 is a multi-level cell (MLC) that is capable of storing more than a single bit of data in more than four memory states. For example, the MLC can store two bits per cell, three bits per cell (also known as trinary-level cell (TLC)), or four bits per cell (also known as a quad-level cell (QLC)). Each MLC can be programmed to assume a range of possible nominal storage values. In one example, if each MLC stores two bits of data, then the MLC can be programmed to write one of three possible nominal storage values to the cell, while a fourth nominal storage value in addition to the three possible nominal storage values can be used for representing the erased state.

As shown in FIG. 9, each NAND memory string 908 can include a source selective gate (SSG) 910 at its source end and a drain selective gate (DSG) 912 at its drain end. SSG 910 and DSG 912 can be configured to activate selected NAND memory strings 908 (columns of the array) during read and program operations. In some examples, the sources of NAND memory strings 908 in a same block 904 are coupled through a same source line (SL) 914, e.g., a common SL.

According to some examples, all NAND memory strings 908 in the same block 904 have an array common source (ACS). According to some examples, DSG 912 of each NAND memory string 908 is coupled to a respective bit line 916 from which data can be read or written via an output bus (not shown). In some examples, each NAND memory string 908 is configured to be selected or deselected by at least one of applying a select voltage (e.g., above the threshold voltage of the transistor having DSG 912) or a deselect voltage (e.g., 0 V) to respective DSG 912 through one or more DSG lines 913 or applying a select voltage (e.g., above the threshold voltage of the transistor having SSG 910) or a deselect voltage (e.g., 0 V) to respective SSG 910 through one or more SSG lines 915.

As shown in FIG. 9, NAND memory strings 908 can be organized into multiple blocks 904, each of which can have a common source line 914, e.g., coupled to the ground. In some examples, each block 904 is the basic data unit for erase operations, i.e., all memory cells 906 on the same block 904 are erased at the same time. To erase memory cells 906 in a selected block 904, source lines 914 coupled to selected block 904 as well as unselected blocks 904 in the same plane as selected block 904 can be biased with an erase voltage (Vers), such as a high positive voltage (e.g., 20 V or more).

It is understood that in some examples, erase operation may be performed at a half-block level, a quarter-block level, or a level having any suitable number of blocks or any suitable fractions of a block. Memory cells 906 of adjacent NAND memory strings 908 can be coupled through word lines 918 that select which row of memory cells 906 is affected by read and program operations. In some examples, each word line 918 is coupled to a page 920 of memory cells 906, and the page 920 is the basic data unit for program operations. The size of one page 920 in bits can relate to the number of NAND memory strings 908 coupled by word line 918 in one block 904. Each word line 918 can include a plurality of control gates (gate electrodes) at each memory cell 906 in respective page 920 and a gate line coupling the control gates. Page 920 shown in FIG. 9 may include a row of memory cells 906 or multiple rows of memory cells 906 in the same layer that shares one word line voltage.

In some examples, the physical device structure of the NAND memory string 908 may include the structures as shown in FIG. 1G and FIGS. 2-4. A NAND memory string 908 may include one or more channel columns 140 or one or more channel columns 240. A NAND memory string may also include a plurality of channel columns disposed and coupled in a stack.

The word lines 918 in FIG. 9 may correspond to the gate layers 122 in FIG. 1G, or correspond to the gate layers 222 in FIGS. 2-4. The gate layer 122 or the gate layer 222 at the top of the stacked structure may extend laterally as a top select gate line, the gate layer 411 at the bottom of the stacked structure 410 may extend laterally as a bottom select gate line, and the gate layer extending laterally between the top select gate line and the bottom selection gate line may serve as a word line layer.

Referring back to FIG. 9, peripheral circuits 902 can be coupled to memory array 901 through bit lines 916, word lines 918, source lines 914, SSG lines 915, and DSG lines 913. Peripheral circuits 902 can include any suitable analog, digital, and mixed-signal circuits for facilitating the operations of memory array 901 by applying and sensing at least one of voltage signals or current signals to and from each target memory cell 906 through bit lines 916, word lines 918, source lines 914, SSG lines 915, and DSG lines 913. Peripheral circuits 902 can include various types of peripheral circuits formed using metal-oxide-semiconductor (MOS) technologies. The memory array 901 may include a plurality of arranged channel columns 140 or a plurality of arranged channel columns 240. The example of the present disclosure does not limit the arrangement and number of channel columns 240.

In some examples, FIG. 10 illustrates some example peripheral circuits, the peripheral circuits 902 including a page buffer/sense amplifier 1004, a column decoder/bit line driver 1006, a row decoder/word line driver 1008, a voltage generator 1010, control logic unit 1012, registers 1014, an interface 1016, and a data bus 1018. It is understood that in some examples, additional peripheral circuits not shown in FIG. 10 may be included as well.

Page buffer/sense amplifier 1004 can be configured to read and program (write) data from and to memory array 901 according to the control signals from control logic unit 1012. In one example, page buffer/sense amplifier 1004 may store one page of program data (write data) to be programmed into one page 920 of memory array 901. In another example, page buffer/sense amplifier 1004 may perform program verify operations to ensure that the data has been properly programmed into memory cells 906 coupled to selected word lines 918. In still another example, page buffer/sense amplifier 1004 may also sense the low power signals from bit line 916 that represents a data bit stored in memory cell 906 and amplify the small voltage swing to recognizable logic levels in a read operation. Column decoder/bit line driver 1006 can be configured to be controlled by control logic unit 1012 and select one or more NAND memory strings 908 by applying bit line voltages generated from voltage generator 1010.

Row decoder/word line driver 1008 can be configured to be controlled by control logic unit 1012 and select/deselect blocks 904 of memory array 901 and select/deselect word lines 918 of block 904. Row decoder/word line driver 1008 can be further configured to drive word lines 918 using word line voltages generated from voltage generator 1010. In some examples, row decoder/word line driver 1008 can also select/deselect and drive SSG lines 915 and DSG lines 913 as well. As described below in detail, row decoder/word line driver 1008 is configured to perform erase operations on the memory cells 906 coupled to the selected word line(s) 918. Voltage generator 1010 can be configured to be controlled by control logic unit 1012 and generate the word line voltages (e.g., read voltage, program voltage, pass voltage, local voltage, verification voltage, etc.), bit line voltages, and source line voltages to be supplied to memory array 901.

Control logic unit 1012 can be coupled to each peripheral circuit described above and configured to control operations of each peripheral circuit. Registers 1014 can be coupled to control logic unit 1012 and include status registers, command registers, and address registers for storing status information, command operation codes (OP codes), and command addresses for controlling the operations of each peripheral circuit. Interface 1016 may be coupled to control logic unit 1012 and act as a control buffer to buffer and relay control commands received from a host (not shown) to control logic unit 1012, and to buffer and relay status information received from control logic unit 1012 to the host. Interface 1016 may further be coupled to column decoder/bit line driver 1006 via data bus 1018 and act as a data I/O interface and data buffer to buffer and relay data to or from memory array 901.

According to a first aspect of an example of the present disclosure, a three-dimensional memory is provided, comprising:
a stack structure comprising alternating stacked gate layers and dielectric layers;
a plurality of channel columns penetrating the stack structure in a first direction and comprising: a barrier layer, a storage layer, a tunneling layer, and a channel layer arranged in sequence; and
a plurality of isolation structures located between the dielectric layers and the tunneling layer in a second direction perpendicular to the first direction;
wherein the isolation structures penetrating at least a portion of the storage layer in the second direction.

In some examples, a size of a portion of the storage layer in the first direction between two of the isolation structures that are adjacent in the first direction is greater than a size of the gate layers in the first direction.

In some examples, an orthographic projection in the second direction of the portion of the storage layer between two of the isolation structures that are adjacent in the first direction overlaps at least partially with an orthographic projection in the second direction of the gate layers.

In some examples, an orthographic projection in the second direction of the isolation structures falls within an orthographic projection in the second direction of the dielectric layers.

In some examples, the isolation structures penetrate the storage layer in the second direction.

In some examples, the storage layer is divided into a plurality of first storage sublayers in the first direction by the isolation structures.

In some examples, the isolation structures penetrate a portion of a thickness of the storage layer in the second direction, and a thickness of a portion of the storage layer that is not penetrated by the isolation structures in the second direction is smaller than a preset value.

In some examples, a portion of the storage layer between two of the isolation structures that are adjacent in the first direction constitutes a second storage sublayer.

In some examples, an orthographic projection in the second direction of the gate layers falls between orthographic projections in the second direction of two of the isolation structures that are adjacent in the first direction.

In some examples, the isolation structures extend toward the dielectric layers, and a portion of the isolation structures extend into between two of the gate layers that are adjacent.

In some examples, the barrier layer is located between the dielectric layers and the isolation structures, and a portion of the isolation structures that extends into the dielectric layers is surrounded by the barrier layer.

In some examples, the barrier layer comprises a first barrier sublayer and a second barrier sublayer; wherein the second barrier sublayer being located between the first barrier sublayer and the storage layer, and the first barrier sublayer comprising a high dielectric material.

In some examples, the first barrier layer comprises an aluminum oxide material, and the second barrier layer comprises a silicon oxide material.

According to a second aspect of an example of the present disclosure, a manufacturing method of a three-dimensional memory is provided, comprising:
forming a laminated structure, wherein the laminated structure comprising alternating stacked dielectric layers and sacrificial layers;
forming a plurality of channel holes penetrating the laminated structure in a first direction;
etching a portion of the dielectric layers through the channel holes in a second direction perpendicular to the first direction to form a void between two of the sacrificial layers that are adjacent;
forming a barrier layer on a sidewall of the channel holes;
forming isolation structures in the void;
forming a storage layer on the barrier layer in the second direction, wherein the isolation structures penetrating at least a portion of the storage layer in the second direction; an orthographic projection in the second direction of the portion of the storage layer between two of the isolation structures that are adjacent in the first direction overlaps at least partially with an orthographic projection in the second direction of the sacrificial layers; and
forming a tunneling layer and a channel layer covering the storage layer in sequence in the second direction, wherein the isolation structures being located between the dielectric layers and the tunneling layer in the second direction.

In some examples, a size of a portion of the storage layer in the first direction between two of the isolation structures that are adjacent in the first direction is greater than a size of the sacrificial layers in the first direction.

In some examples, an orthographic projection in the second direction of the isolation structures falls within an orthographic projection in the second direction of the dielectric layers. In some examples, the method of forming the isolation structures comprises:
forming isolation material layers covering the barrier layer and filling the void; and
removing the isolation material layers covering the barrier layer, and oxidizing remainder of the isolation material layers to form the isolation structures.

In some examples, constituent material of the isolation material layers comprises at least one of: monocrystalline silicon, polysilicon, and amorphous silicon.

In some examples, the method of forming the storage layer comprises:
forming a storage material layer covering the barrier layer and the isolation structures; and
etching the storage material layer to expose the isolation structures to form the storage layer;
wherein the storage layer being divided into a plurality of first storage sublayers by the isolation structures.

In some examples, the method of forming the storage layer comprises:
forming a storage material layer covering the barrier layer and the isolation structures; and
etching the storage material layer to reduce its thickness in the second direction such that the thickness of a region of the formed storage layer corresponding to the isolation structures in the second direction is smaller than a preset value; wherein a portion of the storage layer between two of the isolation structures that are adjacent in the first direction forming a second storage sublayer.

In some examples, the method of manufacturing the barrier layer comprises:
forming a first barrier sublayer on the sidewall of the channel hole comprising the void; and
forming a second barrier sublayer covering the first barrier sublayer; wherein the first barrier sublayer comprising a high dielectric material.

In some examples, the manufacturing method further comprises:
replacing the sacrificial layers with a conductive material to form gate layers.

According to a third aspect of an example of the present disclosure, a memory system is provided, comprising:
a memory device comprising one or more three-dimensional memories according to any one of claims 1 to 12; and
a memory controller coupled to the memory device and configured to control the memory device.

A three-dimensional memory according to an example of the present disclosure comprises a stack structure comprising alternating stacked gate layers and dielectric layers; channel columns penetrating the stack structure in a first direction and comprising: a barrier layer, a storage layer, a tunneling layer, and a channel layer arranged in sequence; and a plurality of isolation structures disposed between the dielectric layers and the tunneling layer in a second direction perpendicular to the first direction; wherein the isolation structures penetrating at least a portion of the storage layer in the second direction. The portion of the storage layer between two of the isolation structures that are adjacent in the first direction functions as a charge trap layer, such that one gate layer only controls a portion of the storage layer between the two of the isolation structures. The storage layer is electrically cut off by the isolation structures, so that a portion of the storage layers corresponding to adjacent gate layers will not leak electrons to each other, thereby improving the stability of the three-dimensional memory.

The forgoing description is only a specific example of the present disclosure, but the protection scope of the present disclosure is not limited thereto. Anyone skilled in the art can easily conceive of changes or substitutions within the technical scope of the present disclosure, which should fall within the protection scope of the present disclosure. Therefore, the protection scope of the present disclosure should be determined by the protection scope of the claims.

What is claimed is:

1. A three-dimensional memory, comprising:
a stack structure comprising alternating stacked gate layers and dielectric layers;
a plurality of channel columns penetrating the stack structure in a first direction and comprising: a barrier layer, a storage layer, a tunneling layer, and a channel layer arranged in sequence; and
a plurality of isolation structures located between the dielectric layers and the tunneling layer in a second direction perpendicular to the first direction, wherein the isolation structures penetrating at least a portion of the storage layer in the second direction.

2. The three-dimensional memory of claim 1, wherein a size of a portion of the storage layer in the first direction between two of the isolation structures that are adjacent in the first direction is greater than a size of the gate layers in the first direction.

3. The three-dimensional memory of claim 2, wherein an orthographic projection in the second direction of the portion of the storage layer between two of the isolation structures that are adjacent in the first direction overlaps at least partially with an orthographic projection in the second direction of the gate layers.

4. The three-dimensional memory of claim 1, wherein an orthographic projection in the second direction of the isolation structures falls within an orthographic projection in the second direction of the dielectric layers.

5. The three-dimensional memory of claim 1, wherein the isolation structures penetrate the storage layer in the second direction.

6. The three-dimensional memory of claim 5, wherein the storage layer is divided into a plurality of first storage sublayers in the first direction by the isolation structures.

7. The three-dimensional memory of claim 1, wherein the isolation structures penetrate a portion of a thickness of the storage layer in the second direction, and a thickness of a portion of the storage layer that is not penetrated by the isolation structures in the second direction is smaller than a preset value.

8. The three-dimensional memory of claim 7, wherein a portion of the storage layer between two of the isolation structures that are adjacent in the first direction constitutes a second storage sublayer.

9. The three-dimensional memory of claim 1, wherein an orthographic projection in the second direction of the gate layers falls between orthographic projections in the second direction of two of the isolation structures that are adjacent in the first direction.

10. The three-dimensional memory of claim 1, wherein the isolation structures extend toward the dielectric layers, and a portion of the isolation structures extend into between two of the gate layers that are adjacent.

11. The three-dimensional memory of claim 10, wherein the barrier layer is located between the dielectric layers and the isolation structures, and a portion of the isolation structures that extends into the dielectric layers is surrounded by the barrier layer.

12. The three-dimensional memory of claim 1, wherein the barrier layer comprises a first barrier sublayer and a second barrier sublayer, wherein the second barrier sublayer being located between the first barrier sublayer and the storage layer, and the first barrier sublayer comprising a high dielectric material.

13. The three-dimensional memory of claim 12, wherein the first barrier sublayer comprises an aluminum oxide material, and the second barrier sublayer comprises a silicon oxide material.

14. A manufacturing method of a three-dimensional memory, comprising:
forming a laminated structure, wherein the laminated structure comprising alternating stacked dielectric layers and sacrificial layers;
forming a plurality of channel holes penetrating the laminated structure in a first direction;
etching a portion of the dielectric layers through the channel holes in a second direction perpendicular to the first direction to form a void between two of the sacrificial layers that are adjacent;
forming a barrier layer on a sidewall of the channel holes;
forming isolation structures in the void;
forming a storage layer on the barrier layer, wherein the isolation structures penetrating at least a portion of the storage layer in the second direction; and
forming a tunneling layer and a channel layer covering the storage layer in sequence, wherein the isolation structures being located between the dielectric layers and the tunneling layer in the second direction.

15. The manufacturing method of claim 14, wherein a size of a portion of the storage layer in the first direction between two of the isolation structures that are adjacent in the first direction is greater than a size of the sacrificial layers in the first direction.

16. The manufacturing method of claim 14, wherein the method of forming the isolation structures comprises:
forming isolation material layers covering the barrier layer and filling the void; and
removing the isolation material layers covering the barrier layer, and oxidizing remainder of the isolation material layers to form the isolation structures.

17. The manufacturing method of claim 14, wherein the method of forming the storage layer comprises:
forming a storage material layer covering the barrier layer and the isolation structures; and
etching the storage material layer to expose the isolation structures to form the storage layer, wherein the storage layer being divided into a plurality of first storage sublayers by the isolation structures.

18. The manufacturing method of claim 14, wherein the method of forming the storage layer comprises:
forming a storage material layer covering the barrier layer and the isolation structures; and
etching the storage material layer to reduce its thickness in the second direction such that the thickness of a region of the formed storage layer corresponding to the isolation structures in the second direction is smaller than a preset value, wherein a portion of the storage layer between two of the isolation structures that are adjacent in the first direction forming a second storage sublayer.

19. The manufacturing method of claim 14, wherein the manufacturing method of the barrier layer comprises:
forming a first barrier sublayer on the sidewall of the channel hole comprising the void;
forming a second barrier sublayer covering the first barrier sublayer; wherein the first barrier sublayer comprising a high dielectric material; and
replacing the sacrificial layers with a conductive material to form gate layers.

20. A memory system comprising:
a memory device comprising one or more three-dimensional memories, wherein the three-dimensional memories comprising:
a stack structure comprising alternating stacked gate layers and dielectric layers;
a plurality of channel columns penetrating the stack structure in a first direction and comprising: a barrier layer, a storage layer, a tunneling layer, and a channel layer arranged in sequence; and
a plurality of isolation structures located between the dielectric layers and the tunneling layer in a second direction perpendicular to the first direction;
wherein the isolation structures penetrating at least a portion of the storage layer in the second direction; and
a memory controller coupled to the memory device and configured to control the memory device.
